(19) United States
(12) Patent Application Publication
(10) Pub. No.: US 2003/0084561 A1
(43) Pub. Date: May 8, 2003

(54) Method of manufacturing bolt-tightened langevin type transducer

(75) Inventor: Norihiro Yamada, Hachioji-shi (JP)

Correspondence Address: OSTROLENK FABER GERB & SOFFEN, 1180 AVENUE OF THE AMERICAS, NEW YORK, NY, 100368403

(73) Assignee: Olympus Optical Co. Ltd.

(21) Appl. No.: 10/285,795

(22) Filed: Oct. 31, 2002

(30) Foreign Application Priority Data
Nov. 7, 2001 (JP) 2001-342188

(51) Int. Cl. G01R 1/00; H04R 17/00; B23Q 17/00

(52) U.S. Cl. 29/593; 29/25.35; 29/25.41; 29/407.02

(57) ABSTRACT

The electrostatic capacitance of piezoelectric elements constituting a Langevin oscillator is measured, and a bolt is tightened so that the measurement value becomes optimum.

### CROSS-REFERENCE TO RELATED APPLICATIONS

This application is based upon and claims the benefit of priority from the prior Japanese Patent Application No. 2001-342188, filed Nov. 7, 2001, the entire contents of which are incorporated herein by reference.

### BACKGROUND OF THE INVENTION

1. Field of the Invention

The present invention relates to a manufacturing method of a bolt-tightened Langevin type transducer.

2. Description of the Related Art

A bolt-tightened Langevin transducer generally comprises a plurality of piezoelectric elements 2 having an electrical distortion effect, electrodes 3a and 3b interposed between said piezoelectric elements 2, a pair of metal blocks 4 and 5 holding said piezoelectric elements 2 and electrodes 3, and a bolt 6 tightening said metal blocks 4 and 5, as shown in FIG. 1. The force of the bolt 6 pressing the piezoelectric elements 2 is controlled by the tightening torque of a torque wrench or the like.

The pressing force applied to the piezoelectric elements 2 greatly influences the transducer performance. If the pressing force is less than an optimum value, for example, the tensile strength of the piezoelectric elements is exceeded by the tensile stress generated by oscillation when the transducer is powered and driven. As a result, the transducer may be broken. Whereas, if the pressing force is larger than the optimum value, the compressive strength of the piezoelectric elements is exceeded by the compressive stress generated by oscillation and the transducer may also be broken.

It is important as mentioned above to control the pressing force applied to the piezoelectric elements. However, there has been a problem in controlling the pressing force based on the tightening torque. The friction coefficient varies depending on the surface roughness and flatness of each member, and consequently the pressing force applied to the piezoelectric elements also varies. As a result, the quality of Langevin transducer 1 becomes unstable.

One solution has been suggested by Jpn. Pat. Appln. KOKAI Publication No. 51-111094. The amount of electric charge of the piezoelectric elements generated by the electrical distortion effect is previously detected and used as a reference when tightening the metal blocks with a bolt, so that the pressing force applied to the piezoelectric elements is always held in an optimum range.

However, the electric charge, or the current of the piezoelectric elements generated when the bolt is tightened, is a pulse wave of 1-100 μsec, which is difficult to measure exactly. Besides, the generated current flows directly into a measuring instrument such as an oscilloscope, which may be damaged as a result.

### BRIEF SUMMARY OF THE INVENTION

An object of the present invention is to provide a method of manufacturing a stable bolt-tightened Langevin transducer.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the embodiments given below, serve to explain the principles of the invention.

FIG. 1 is a block diagram of an apparatus used in a method of manufacturing a bolt-tightened Langevin transducer according to an embodiment of the present invention;

FIG. 2 is a graph showing the characteristics of a diode according to the embodiment of the invention;

FIG. 3 is a diagram showing a modification of a rectifier circuit according to the embodiment of the invention;

FIG. 4 is a diagram showing another modification of a rectifier circuit according to the embodiment of the invention; and

FIG. 5 is a view explaining a conventional method of manufacturing a bolt-tightened Langevin transducer.

### DETAILED DESCRIPTION OF THE INVENTION

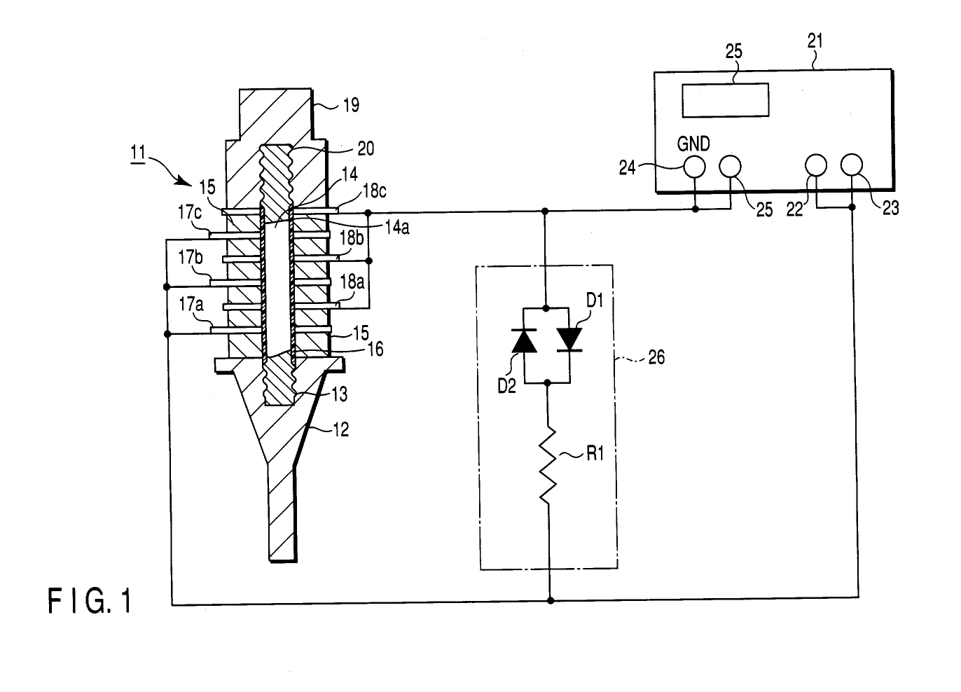

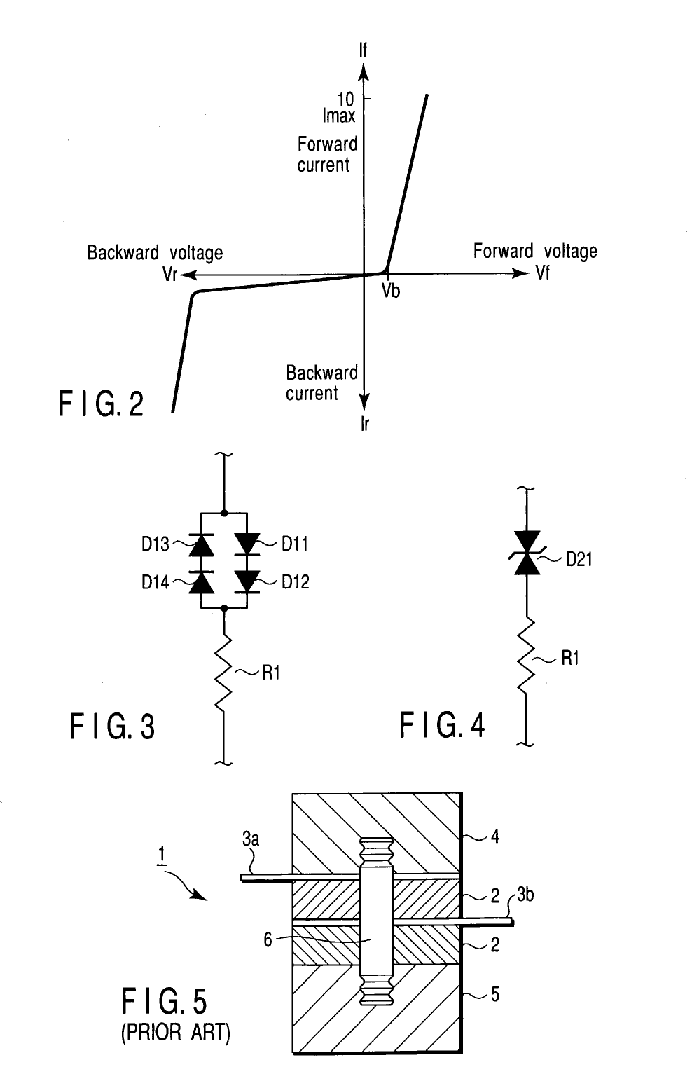

An embodiment of the present invention will be explained hereinafter with reference to FIG. 1 and FIG. 2.

FIG. 1 shows a device used in a method of manufacturing a bolt-tightened Langevin transducer. In FIG. 1, a reference numeral 11 denotes a bolt-tightened Langevin type transducer. The Langevin transducer 11 has at one end a horn 12 having a conical throttle. The central portion of the conical bottom of the horn 12 has an internal thread 13.

A reference numeral 14 denotes a bolt having threads at its both ends. The outer unthreaded circumference of the bolt 14 is covered by a tubular insulating coating material 14a.

The internal thread 13 in the center of the circular bottom of the horn 12 engages with the external thread at one end of the bolt 14.

A reference numeral 15 denotes a ring-like piezoelectric element, having at its center a through hole 16 to insert the bolt 14. The piezoelectric element 15 is made of ceramics having an electrical distortion effect, whose end-faces are pre-polarized in the thickness direction so that the end-faces have positive and negative poles. Further, the end-faces in the thickness direction of the piezoelectric element 15 are formed as Ni-plated electrodes.

Reference numerals 17a-17c denote positive electrode plates, having at the center a through hole to insert the bolt 14. Reference numerals 18a-18c denote negative electrode plates, having at the center a through hole to insert the bolt 14.

The piezoelectric elements 15, positive electrode plates 17a-17c and negative electrode plates 18a-18c are sequentially inserted onto the bolt 14 and each piled up alternately from the circular bottom of the horn 12; a layer of piezoelectric element 15, positive electrode plate 17a and piezoelectric element 15 is piled up three times. At this time, the piezoelectric elements 15 are piled up holding the positive electrode plates 17a-17c and negative electrode plates 18a-18c, so that the same electrode faces become to be opposite to each other.

The external thread at the other end of the bolt 14 engages with the internal thread 20 in the center of the circular bottom of a substantially cylindrical lining plate 19.

The positive electrode plates 17a-19c are connected to a measurement signal application terminal 22 and a voltage detection positive terminal 23 of a capacitance meter 21. The negative electrode plates 18a-18c are connected to a voltage detection GND terminal 24 and a measurement current detection terminal 25 of the capacitance meter 21. The capacitance meter 21 outputs a measurement signal of 0.5V/1 kHz, for example, through the measurement signal application terminal 22, takes in the resultant current through the measurement current detection terminal 25, calculates the electrostatic capacitance of the piezoelectric element 15, and displays it in a display window 25. The internal impedance of the capacitance meter 21 is set to 1 kΩ, for example.

A rectifier circuit 26 is connected between the positive electrode plates 17a-17c and negative electrode plates 18a-18b. Namely, the rectifier circuit 26 is connected in parallel between the Langevin transducer 11 and capacitance meter 21.

In the rectifier circuit 26, diodes D1 and D2 are connected in parallel to be opposite to each other, and one end of the parallel connection is connected to the positive electrode plates 17a-17c through a 50 Ω resistor R1, for example, and the other end is connected to the negative electrode plates 18a 18c.

The diodes D1 and G2 have the same characteristics. As shown in FIG. 2, the forward voltage drop is 2.5V, and the allowable current is Imax. When the diodes D1 and D2 conduct in the forward direction, the forward resistance is 0.1 mΩ.

Description will now be given on the operations of the above-mentioned embodiment of the present invention. To construct this embodiment, first cover the surface of the bolt 14 except the threads by the insulating coating material 14a. Screw one end of the bolt 14 into the internal threads 13 of the horn 12. Insert and alternately layer the piezoelectric elements 15, positive electrode plates 17a-17c and negative electrode plates 18a-18c. Screw the lining plate 19 lightly into the bolt 14 to fix temporarily.

Next, connect the measurement signal application terminal 22 and voltage detection positive terminal 23 of the capacitance meter 21 to the positive electrode plates 17a-17c of the transducer 11, and connect the voltage detection GND 24 and measurement current detection terminal 25 to the negative electrode plates 18a-18c. Further, connect the rectifier circuit 26 in parallel between the transducer 11 and capacitance meter 21.

With this structure, the current generated by the electrical distortion effect of the piezoelectric element 15 when tightening the bolt, flows through the rectifier circuit 26 irrespective of the current direction. That is, the current generated when the bolt is tightened will not flow into the capacitance meter. Therefore, the capacitance meter 21 will not be damaged by the current flowing thereinto.

Then, supply power to the capacitance meter 21 to generate a measurement signal. Tighten the lining plate 19 with a wrench.

Measure the electrostatic capacitance of the transducer 11 in real time with the capacitance meter 21, and tighten the bolt until the measured electrostatic capacitance reaches a predetermined value.

In other words, measure the electrostatic capacitance of the piezoelectric element 15 by utilizing the fact that the electrostatic capacitance is proportional to the pressing force, and tighten the bolt until the electrostatic capacitance reaches the optimum value. This makes it possible to set the force pressing the piezoelectric elements to the optimum value. Thus, the quality of the Langevin transducer 11 can be stabilized.

The voltage Veff generated in the Langevin transducer 11 when the bolt is tightened is 100-200V. The allowable current Imax of the rectifier circuit 26 is 10A, as shown in FIG. 2. Therefore, Veff/Imax is 10-20 Ω.

On the other hand, the impedance of the rectifier circuit 26 is substantially negligible when the diodes D1 and D2 conduct, and can be considered to be 50 Ω that is the impedance of the resistor R1.

The impedance of the capacitance meter 21 is 1 kΩ. Therefore, Veff/Imax=10−20 Ω<Circuit impedance=50 Ω<Capacitance meter impedance=1 kΩ.

That is, Veff/Imax is smaller than the rectifier circuit impedance, and Veff/Rectifier circuit impedance can be smaller than Imax. The Veff/rectifier circuit impedance can set the current flowing in the rectifier circuit 26 to be smaller than the allowable current Imax of the rectifier circuit 26, by the voltage Veff generated between the positive electrode plates 17a-17c and negative electrode plates 18a-18c when tightening the Langevin transducer with a bolt.

Thus, the rectifier circuit 26 will not be damaged by the current generated by the voltage Veff generated between the positive electrode plates 17a-17c and negative electrode plates 18a-18c when the bolt is tightened.

Therefore, if the impedance of the capacitance meter 21 connected to both ends of the rectifier circuit 26 is larger than the impedance of the rectifier circuit 26, the capacitance meter 21 will not be damaged.

The measurement signal voltage of the capacitance meter 21 is 0.5V. The forward voltage drop of the diodes D1 and D2 is 2.5V. Since the forward voltage drop of the diodes D1 and D2 constituting the rectifier circuit 26 is larger than the measurement signal voltage outputted from the capacitance meter 21, the diode D1 or D2 will not conduct in the forward direction.

Therefore, the measurement signal voltage from the capacitance meter 21 is applied only across the electrodes of the Langevin transducer 11, and the electrostatic capacity of the piezoelectric elements 15 comprising the Langevin transducer 11 can be accurately measured.

The rectifier circuit 26 of the above-mentioned embodiment can be constructed as shown in FIG. 3. Two diodes D11, D12 and another two diodes D13, D14 are connected in series, respectively. These two pairs of diodes are connected in parallel to be opposite to each other. A 50 Ω resistor R1 is further connected in series to these two pairs of diodes. The characteristics of the diodes D11-D14 are the same as those of the diodes D1 and D2.

By connecting two diodes in series within the rectifier circuit 26, the capacitance of the rectifier circuit 26 can be reduced to half of the rectifier circuit 26 shown in FIG. 1.

Therefore, the rectifier circuit 26 can be constructed as shown in FIG. 4. A bipolar diode D21 and a 50 Ω resistor R1 are connected in series.

By using the bipolar diode D21 in the rectifier circuit 26 of FIG. 1, the number of parts can be reduced.

Even by using the rectifier circuit of FIG. 3 or 4 as the rectifier circuit 26 of FIG. 1, the relation Veff/Imax=10−20 Ω<Circuit impedance=50 Ω<capacitance meter impedance=1 kΩ is established, and the same effect as the above-mentioned embodiment can be obtained.

Further, when the rectifier circuit of FIG. 3 or 4 is used as the rectifier circuit 26 of FIG. 1, the same effect as the above-mentioned embodiment can be obtained by setting the measurement signal voltage to the value with which the diodes constituting the rectifier circuit 26 do not conduct in the forward direction.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method of manufacturing a bolt-tightened Langevin transducer, comprising:
tightening a bolt according to an electrostatic capacitance of piezoelectric elements which comprise the Langevin transducer.

2. A method according to claim 1, wherein a rectifier circuit comprising a resistor and diodes connected in parallel and is opposite polarity is connected between both electrodes of said Langevin transducer, and a capacitance meter is connected to ends of said rectifier circuit to measure the electrostatic capacitance of said piezoelectric elements.

3. A method according to claim 2, wherein said rectifier circuit has an impedance set at Veff/Imax<Rectifier circuit impedance<Capacitance meter impedance, where Veff is the voltage generated between the electrodes of said Langevin transducer by the electrical distortion effect of said piezoelectric elements when said Langevin transducer is tightened with a bolt, and Imax is the allowable current of said rectifier circuit.

4. A method according to claim 3, wherein said capacitance meter is configured to apply a measurement signal voltage across the electrodes of said Langevin transducer, and to measure the electrostatic capacitance of said Langevin transducer by detecting the current flowing over said electrodes, and a forward voltage drop of the diodes constituting said rectifier circuit is larger than said measurement signal voltage.

5. A method comprising:
measuring electrostatic capacitance of piezoelectric elements which comprise a Langevin transducer; and
tightening a lining plate with a bolt so that the electrostatic capacitance of said piezoelectric elements becomes optimum.

6. A method according to claim 5, wherein a rectifier circuit comprising a resistor and diodes connected in parallel and in opposite polarity is connected between both electrodes of said Langevin transducer, and a capacitance meter is connected to ends of said rectifier circuit to measure the electrostatic capacitance of said piezoelectric elements.

7. A method according to claim 6, wherein said rectifier circuit has an impedance set at Veff/Imax <Rectifier circuit impedance <Capacitance meter impedance, where Veff is the voltage generated between the electrodes of said Langevin transducer by the electrical distortion effect of said piezoelectric elements when said Langevin transducer is tightened with a bolt, and Imax is the allowable current of said rectifier circuit.

8. A method according to claim 7, wherein said capacitance meter is configured to apply a measurement signal voltage across the electrodes of said Langevin transducer, and to measure the electrostatic capacitance of said Langevin transducer by detecting the current flowing over said electrodes, and a forward voltage drop of the diodes constituting said rectifier circuit is larger than said measurement signal voltage.
